(19) United States
(12) Patent Application Publication
(10) Pub. No.: US 2025/0129464 A1
(43) Pub. Date: Apr. 24, 2025

(54) SURFACE TREATMENT APPARATUS AND SURFACE TREATMENT METHOD

(71) Applicant: Shibaura Machine Co., Ltd., Tokyo (JP)

(72) Inventors: Mitsunori KOKUBO, Numazu-shi (JP); Satoshi FUKUYAMA, Numazu-shi (JP); Kazuhiro FUKADA, Sunto-gun (JP); Rintaro SUEKI, Numazu-shi (JP); Yoshiaki KURIHARA, Sunto-gun (JP); Takeshi NAMBA, Numazu-shi (JP)

(73) Assignee: Shibaura Machine Co., Ltd., Tokyo (JP)

(21) Appl. No.: 18/683,873

(22) PCT Filed: Sep. 8, 2022
(86) PCT No.: PCT/JP2022/033629

§ 371 Date: Feb. 15, 2024

(30) Foreign Application Priority Data
Sep. 15, 2021 (JP) 2021-150602

(51) Int. Cl. C23C 14/00; C23C 14/54

(52) U.S. Cl. CPC C23C 14/0063; C23C 14/54

(57) ABSTRACT

A surface treatment apparatus includes a housing unit that houses at least one workpiece, a placement device in which the workpiece is placed such that the workpiece is substantially orthogonal to a normal direction of an outer peripheral surface of a rotating shaft extending in a horizontal direction, and faces outward, a first rotating device that rotates the placement device) around the rotating shaft in a state where the placement device is housed in the housing unit, a surface treatment device that extends inside the housing unit and in parallel with the rotating shaft and performs surface treatment by supplying gas to a surface of the workpiece, and an exhaust device that is provided inside the housing unit at a position different from a position where the surface treatment device is provided, and adjusts pressure and exhausts gas inside the housing unit.

### TECHNICAL FIELD

The present invention relates to a surface treatment apparatus and a surface treatment method for performing surface treatment such as irradiating a workpiece with plasma.

### BACKGROUND ART

Conventionally, a surface treatment apparatus for forming a metal catalyst layer, a functional group, or the like by cleaning or modifying a surface of a workpiece using plasma, and a surface treatment apparatus for forming a thin film on a surface of a workpiece using a sputtering apparatus are known.

For example, in a film forming apparatus disclosed in Patent Document 1, a plurality of substrates set on a carriage is conveyed to inside the film forming apparatus to perform necessary surface treatment. Further, as an example of the surface treatment, plasma treatment described in Patent Document 2 is known.

### CITATION LIST

### Patent Literature

Patent Document 1: JP H4-231464 A
Patent Document 2: WO 2017/159838 A

### SUMMARY OF INVENTION

### Problems to be Solved by the Invention

A film forming apparatus of Patent Document 1 has a structure suitable for performing surface treatment of a large amount of workpieces, but is not suitable for small-scale production to medium-scale production because of the large scale of the apparatus. In addition, when surface treatment of a workpiece is performed, it is desirable that different types of surface treatment such as sputtering and plasma treatment described in Patent Document 2 can be performed by one apparatus. Further, Patent Documents 1 and 2 describe that an exhaust device for discharging gas filled in a chamber is provided, but do not disclose an installation position of the exhaust device. When the exhaust device is not installed at an appropriate position, it is difficult to achieve a uniform gas flow in the chamber. Thus, there has been a problem that a film thickness on a surface of the workpiece is not uniform.

The present invention has been made in view of the above, and it is an object of the present invention to provide a surface treatment apparatus and a surface treatment method that are suitable for performing surface treatment of a small to medium amount of workpieces, and capable of forming a film with uniform film thickness on a workpiece surface.

### Means for Solving Problem

In order to solve the above problem and achieve the object, a surface treatment apparatus includes: a housing unit that houses at least one workpiece; a placement device that includes a rotating shaft extending in a horizontal direction, and on which the workpiece is placed such that a surface of the workpiece is substantially orthogonal to a normal direction of an outer peripheral surface of the rotating shaft, and faces outward; a first rotating device that rotates the placement device in a predetermined rotation pattern around the rotating shaft in a state where the placement device is housed in the housing unit; a surface treatment device that extends inside the housing unit and in parallel with the rotating shaft, and performs at least one type of surface treatment by supplying gas to the surface of the workpiece; and an exhaust device that is provided inside the housing unit at a position different from a position where the surface treatment device is provided, adjusts pressure inside the housing unit, and exhausts the gas inside the housing unit.

### Effect of the Invention

According to the present invention, a surface treatment apparatus is suitable for performing surface treatment of a small to medium amount of workpieces, and has an effect that a film with uniform film thickness can be formed on a workpiece surface.

### BRIEF DESCRIPTION OF DRAWINGS

FIG. 1 is an external view illustrating an example of a schematic configuration of a surface treatment apparatus according to a first embodiment;

FIG. 2 is an external view illustrating an example of a workpiece mounting part and a workpiece placement part;

FIG. 3 is a diagram illustrating an action of a workpiece conveyance part;

FIG. 4 is a diagram illustrating an example of an internal structure of a chamber according to the first embodiment;

FIG. 5 is a cross-sectional view taken along line A-A of FIG. 4;

FIG. 6 is a cross-sectional view taken along line B-B of FIG. 4;

FIG. 7 is a first cross-sectional view illustrating an example of a configuration of a plasma treatment apparatus;

FIG. 8 is a second cross-sectional view illustrating an example of a configuration of the plasma treatment apparatus;

FIG. 9 is a cross-sectional view illustrating an example of a configuration of a sputtering apparatus.

FIG. 10 is a side view illustrating an example of a pump unit;

FIG. 11 is an XZ cross-sectional view of FIG. 10, and is a diagram illustrating a state in which the pump unit exhausts air in a chamber;

FIG. 12 is a diagram illustrating an example of surface treatment applied to a workpiece by the surface treatment apparatus according to the first embodiment;

FIG. 13 is a diagram illustrating an example of a pressure change in the chamber when the surface treatment apparatus according to the first embodiment performs the surface treatment on the workpiece;

FIG. 14 is a flowchart illustrating an example of a flow of processing performed when the surface treatment apparatus according to the first embodiment performs the surface treatment on the workpiece;

FIG. 15 is an XZ cross-sectional view illustrating an example of a schematic configuration of a plasma treatment apparatus included in a surface treatment apparatus according to a second embodiment; and

FIG. 16 is an XZ cross-sectional view illustrating an example of a schematic configuration of a plasma treatment apparatus included in a surface treatment apparatus according to a modification of the second embodiment.

### DESCRIPTION OF EMBODIMENTS

Hereinafter, embodiments of a surface treatment apparatus according to the present disclosure will be described in detail with reference to the drawings. Note that the present invention is not limited by the embodiments. In addition, components in the following embodiments include those that can be replaced or easily conceived by persons skilled in the art, or those that are substantially the same.

### First Embodiment

The present embodiment is an example of a surface treatment apparatus 10 that irradiates a surface of a workpiece W formed of, for example, a resin material with a plasma gas to generate, for example, a functional group on the surface of the workpiece W, and then forms a thin film by sputtering on the surface of the workpiece W with improved adhesion of a film by generation of the functional group. The workpiece W is a member formed of a resin material such as plastic resin.

### [1. Overall Configuration of Surface Treatment Apparatus]

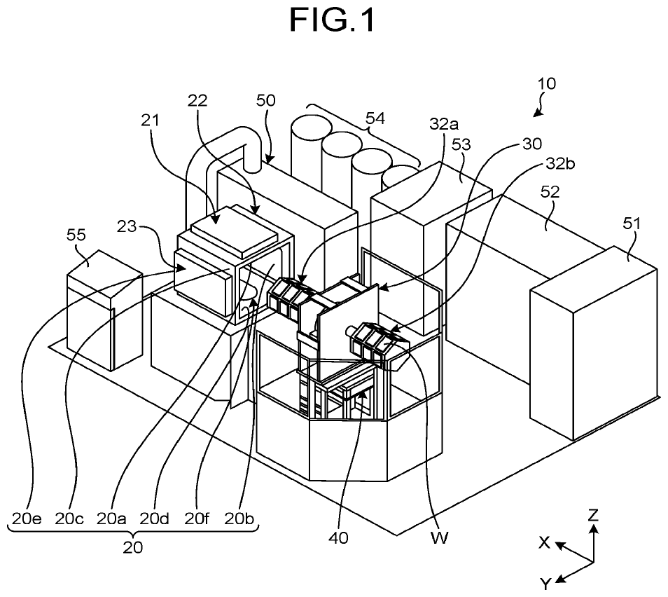

First, a schematic configuration of the surface treatment apparatus 10 will be described with reference to FIG. 1. FIG. 1 is an external view illustrating an example of a schematic configuration of the surface treatment apparatus according to the first embodiment.

As illustrated in FIG. 1, the surface treatment apparatus 10 includes a chamber 20, a workpiece mounting part 30, and a workpiece conveyance part 40. An exhaust apparatus 50 is provided at the back of the chamber 20. The surface treatment apparatus 10 further includes a cooling apparatus 51, a control apparatus 52, a power supply apparatus 53, a gas supply apparatus 54, and an operation panel 55 illustrated in FIG. 1.

The chamber 20 is a sealed reaction vessel that performs surface treatment on the workpiece W housed inside. The chamber 20 is an example of a housing unit in the present disclosure.

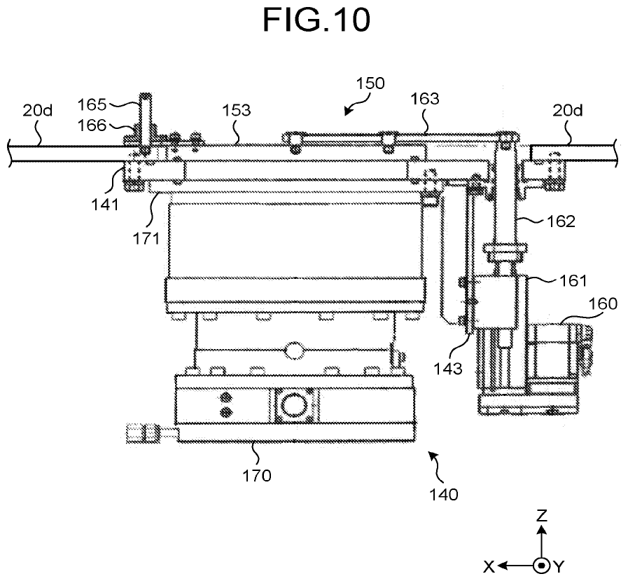

The chamber 20 has, for example, a rectangular parallelepiped shape, and one wall surface is opened to form an opening 20f. A plasma treatment apparatus 21 is installed on an upper wall surface 20a of inner wall surfaces formed inside the chamber 20. In addition, a sputtering apparatus 22 is installed on a side wall surface 20b, and a sputtering apparatus 23 is installed on a side wall surface 20c facing the side wall surface 20b. The plasma treatment apparatus 21 and the sputtering apparatuses 22 and 23 are examples of surface treatment device in the present disclosure. Furthermore, a pump unit 140 (see FIG. 10) for adjusting pressure inside the chamber 20 and exhausting a reaction gas is installed on a bottom surface 20d at a position facing the upper wall surface 20a of the chamber 20. The pump unit 140 will be described in detail later (see FIG. 10). A side wall surface 20e facing the opening 20f is a closed surface. Note that the opening 20f is an example of a housing port in the present disclosure. The chamber 20 is not limited to the rectangular parallelepiped shape, and may be, for example, a shape covered with a curved surface as long as the chamber 20 itself forms a closed space.

The sputtering apparatuses 22 and 23 perform sputtering on the workpiece W housed in the chamber 20 to perform surface treatment for forming a thin film as a base for plating on the workpiece W.

The plasma treatment apparatus 21 converts the reaction gas supplied from the outside into plasma by HCD (hollow cathode discharge). Then, the plasma treatment apparatus 21 generates a precursor by reacting a plasma-converted reaction gas (plasma gas) with a film-forming gas. The precursor generated is sprayed onto the surface of the workpiece W to perform surface treatment of the workpiece W. Specifically, the functional group is generated on the surface of the workpiece W by the surface treatment with the plasma treatment apparatus 21. As a result, it is possible to enhance the adhesion of a thin film when the thin film that will be a base for plating is formed on the surface of the workpiece W in a subsequent step.

The sputtering apparatuses 22 and 23 perform the surface treatment of forming a thin film such as a plating layer on the surface of the workpiece W.

Note that FIG. 1 illustrates an example in which different sputtering apparatuses 22 and 23 are provided on the two side wall surfaces 20b and 20c, respectively, but the number of sputtering apparatuses is not limited to two. In addition, types of the surface treatment device are not limited to the plasma treatment apparatus and the sputtering apparatus.

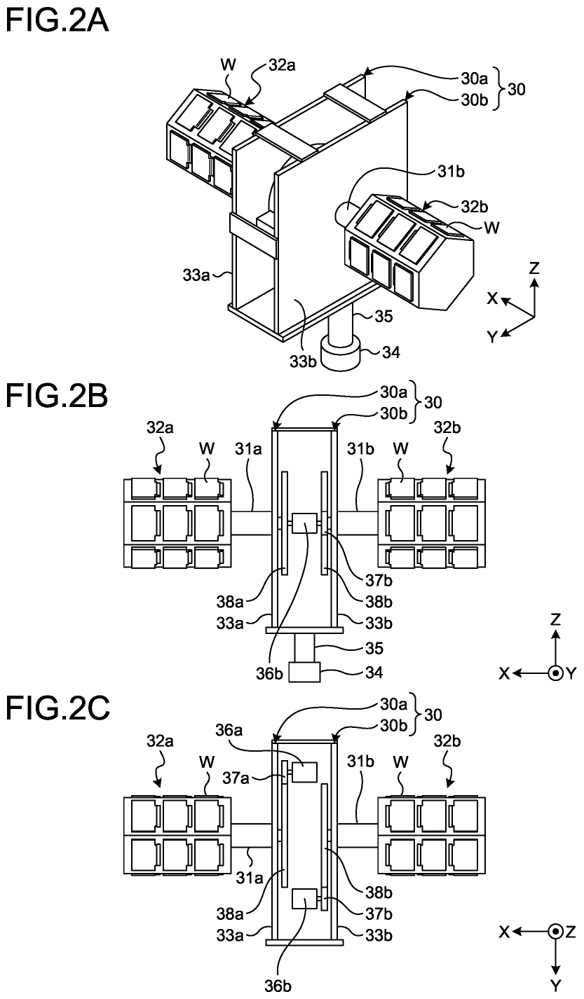

The workpiece mounting part 30 is a part to which workpiece placement parts 32a and 32b for placing the workpiece W are attached. Detailed structures of the workpiece mounting part 30 and the workpiece placement parts 32a and 32b will be described later (see FIG. 2).

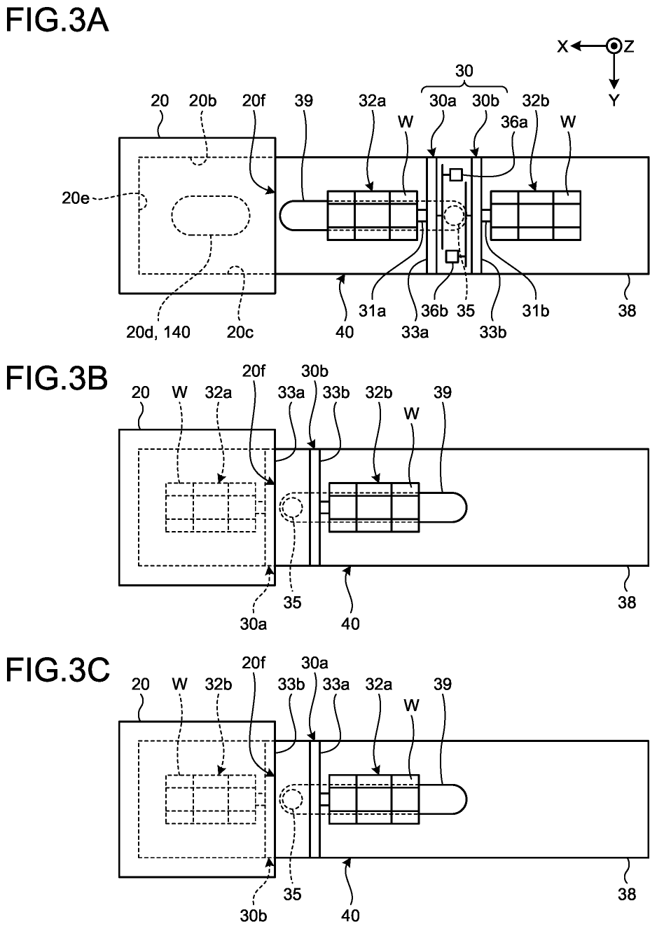

The workpiece conveyance part 40 conveys the workpiece W placed on the workpiece mounting part 30 in an X axis positive direction, thereby housing the workpiece W in the chamber 20. In addition, the workpiece conveyance part 40 conveys the workpiece W placed on the workpiece mounting part 30 in an X-axis negative direction, thereby carrying the workpiece W out of the chamber 20. Note that the workpiece conveyance part 40 is an example of a conveying device in the present disclosure. A detailed structure of the workpiece conveyance part 40 will be described later in detail (see FIG. 3).

The exhaust apparatus 50, the cooling apparatus 51, the control apparatus 52, the power supply apparatus 53, and the gas supply apparatus 54 are provided on the back side (Y-axis negative direction side) of the chamber 20.

The exhaust apparatus 50 depressurize the chamber 20 into a vacuum state. Further, the exhaust apparatus 50 makes pressure in the chamber 20 equal to an atmospheric pressure by opening the inside of the chamber 20 to the atmospheric pressure. Further, the exhaust apparatus 50 exhausts the film-forming gas and the reaction gas accumulated in the chamber 20. The exhaust apparatus 50 includes, for example, a rotary pump or a turbo molecular pump.

The cooling apparatus 51 generates cooling water for cooling equipment, a power supply, and the like.

The control apparatus 52 controls the entire surface treatment apparatus 10.

The power supply apparatus 53 houses a power source to be supplied to each part of the surface treatment apparatus 10.

The gas supply apparatus 54 supplies the film-forming gas and the reaction gas to the chamber 20.

The operation panel 55 is provided near the chamber 20. The operation panel 55 receives an operation instruction for the surface treatment apparatus 10. In addition, the operation panel 55 has a function of displaying an operation status of the surface treatment apparatus 10.

### [2. Placement Structure of Workpiece]

Next, a placement structure of the workpiece W will be described with reference to FIG. 2. FIG. 2 is an external view illustrating an example of a workpiece mounting part and a workpiece placement part.

As illustrated in FIG. 2(a), the workpiece mounting parts 30 (30a, 30b) include rotating shafts 31a and 31b extending horizontally along the X-axis, respectively. The workpiece placement parts 32a and 32b are attached to the ends of the rotating shafts 31a and 31b. At least one workpiece W is placed on each of the workpiece placement parts 32a and 32b such that the surface of the workpiece W is orthogonal to a normal direction of outer peripheral surfaces of the rotating shafts 31a and 31b, and faces outward. Note that the workpiece placement parts 32a and 32b are an example of a placement device in the present disclosure.

The workpiece mounting part 30a and the workpiece mounting part 30b include bases 33a and 33b that support the rotating shafts 31a and 31b, respectively. The bases 33a and 33b are installed in parallel to each other to support the rotating shafts 31a and 31b. The bases 33a and 33b close the opening 20f of the chamber 20 when the workpiece W is housed in the chamber 20. The bases 33a and 33b are an example of a sealing member in the present disclosure.

The workpiece placement parts 32a and 32b are formed in a regular hexagonal prism shape, and three workpieces W can be placed on each side surface. In other words, 18 workpieces W can be placed on each of the workpiece placement parts 32a and 32b. Note that the shape of the workpiece placement parts 32a and 32b and the number of the workpieces W to be placed are not limited thereto.

A workpiece mounting part rotating shaft 35, along a Z-axis, is installed below the bases 33a and 33b. The workpiece mounting part rotating shaft 35 is rotationally driven by a motor 34 to rotate the entire workpiece mounting part 30 around the Z axis. As a result, either one of the workpiece placement parts 32a and 32b can be housed in the chamber 20. The motor 34 is an example of a selection device or a second rotating device in the present disclosure.

As illustrated in FIGS. 2(b) and 2(c), the rotating shaft 31a is rotated by a rotational driving force of a motor 36a. More specifically, the rotational driving force of the motor 36a is transmitted to a gear 38a supporting the rotating shaft 31a via the gear 37a, whereby the rotating shaft 31a rotates. The motor 36a is, for example, a step motor, and controls a rotation angle of the rotating shaft 31a according to an instruction from the control apparatus 52. Similarly, the rotational driving force of a motor 36b rotates the rotating shaft 31b via a gear 37b and a gear 38b. The motors 36a and 36b are an example of a first rotating device in the present disclosure.

### [3. Configuration of Workpiece Conveyance Part]

A configuration of the workpiece conveyance part 40 will be described with reference to FIG. 3. FIG. 3 is a diagram illustrating an action of the workpiece conveyance part.

As illustrated in FIG. 3(a), the workpiece conveyance part 40 includes a support table 38 and a groove 39. The support table 38 supports the workpiece mounting part 30. The groove 39 is a gap through which the workpiece mounting part rotating shaft 35 passes when the workpiece mounting part 30 is conveyed along the X-axis.

FIG. 3(b) is a diagram illustrating a state in which the workpiece conveyance part 40 conveys the workpiece mounting part 30 in the X-axis positive direction to house the workpiece placement part 32a in the chamber 20 when the workpiece mounting part 30 is in the state in FIG. 3(a). At this time, the opening 20f of the chamber 20 is closed by the base 33a.

FIG. 3(c) is a diagram illustrating a state in which the workpiece mounting part rotating shaft 35 is rotated by 180° and then the workpiece conveyance part 40 conveys the workpiece mounting part 30 in the X-axis positive direction to house the workpiece placement part 32b in the chamber 20 when the workpiece mounting part 30 is in the state in FIG. 3(a). At this time, the opening 20f of the chamber 20 is closed by the base 33b.

In the state in FIG. 3(b), the surface treatment apparatus 10 performs the surface treatment on the workpiece W placed on the workpiece placement part 32a. At this time, a worker attaches the workpiece W to be subjected to next surface treatment to the workpiece placement part 32b.

In the state in FIG. 3(c), the surface treatment apparatus 10 performs the surface treatment on the workpiece W placed on the workpiece placement part 32b. At this time, the worker detaches the workpiece W subjected to the surface treatment from the workpiece placement part 32a.

### [4. Internal Structure of Chamber]

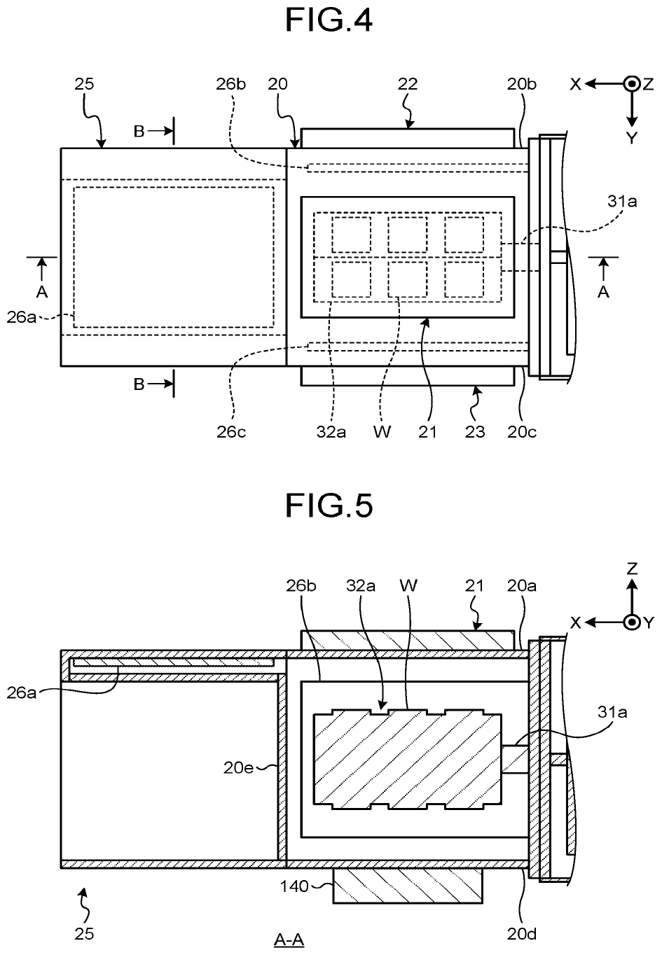

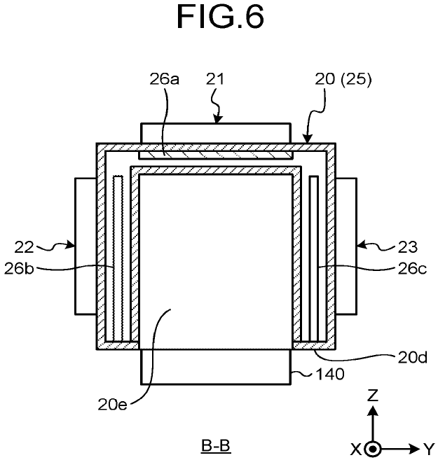

An internal structure of the chamber 20 will be described with reference to FIGS. 4 to 6. FIG. 4 is a diagram illustrating an example of the internal structure of the chamber according to the first embodiment. FIG. 5 is a cross-sectional view taken along line A-A of FIG. 4. FIG. 6 is a cross-sectional view taken along line B-B of FIG. 4.

Plate-shaped shutters 26a, 26b, and 26c are installed inside the chamber 20. The shutters 26a, 26b, and 26c are driven by a motor (not illustrated) according to a command from the control apparatus 52, and shield a surface treatment device other than one of the plurality of surface treatment device performing the surface treatment on the workpiece W. In other words, the shutters 26a, 26b, and 26c are selectively movable along the X axis in response to the command from the control apparatus 52. The shutters 26a, 26b, and 26c are an example of a shielding member in the present disclosure.

For example, FIG. 4 illustrates a state in which the surface treatment apparatus 10 performs the surface treatment on the workpiece W placed on the workpiece placement part 32a by the plasma treatment apparatus 21. At this time, the shutter 26a covering an electrode of the plasma treatment apparatus 21 moves in the X-axis positive direction to be stored in a shutter storage part 25. The shutter 26b covering an electrode of sputtering apparatus 22 and the shutter 26c covering an electrode of the sputtering apparatus 23 both move in the X-axis negative direction to cover the electrodes of the sputtering apparatuses 22 and 23.

As illustrated in FIGS. 5 and 6, the shutter storage part 25 is formed in a shape protruding from the chamber 20 in the X-axis positive direction. In the example of the present embodiment, the shutter storage part 25 is formed on three surfaces (left and right side surfaces and an upper surface) of the chamber 20.

Here, the shutters 26a, 26b, and 26c have been described as having the plate shape, but the shutters 26a, 26b, and 26c may be formed of a fibrous material having heat resistance. In this case, since the shutters 26a, 26b, and 26c have flexibility, the shutter storage part 25 can be formed in a roll type to wind and store the shutters 26a, 26b, and 26c. As a result, protrusion of the shutter storage part 25 in the X-axis direction can be reduced.

Since the plasma treatment by the plasma treatment apparatus 21 is performed in an intermediate flow in which a viscous flow of about 10 Pa and a molecular flow are mixed, a film formation distribution in the workpiece W depends on a position of an exhaust port of the pump unit 140 (see FIG. 10). On the other hand, since sputtering by the sputtering apparatuses 22 and 23 is performed in a vacuum state of a molecular flow region of 1 Pa or less, the film formation distribution is hardly affected by the position of the exhaust port. Therefore, when it is desired to achieve uniform film formation distribution on the workpiece W, it is preferable to install the plasma treatment apparatus 21 at a position facing the position of the exhaust port (bottom surface 20d) in the chamber 20, i.e., at an upper part (upper wall surface 20a) of the chamber 20. The sputtering apparatuses 22 and 23 may be installed anywhere on the inner wall surfaces of the chamber 20, and are not affected as much as the plasma treatment apparatus 21. Therefore, as illustrated in FIG. 4, the sputtering apparatuses 22 and 23 may be installed on the side wall surfaces 20b and 20c of the chamber 20.

### [5. Configuration of Plasma Treatment Apparatus]

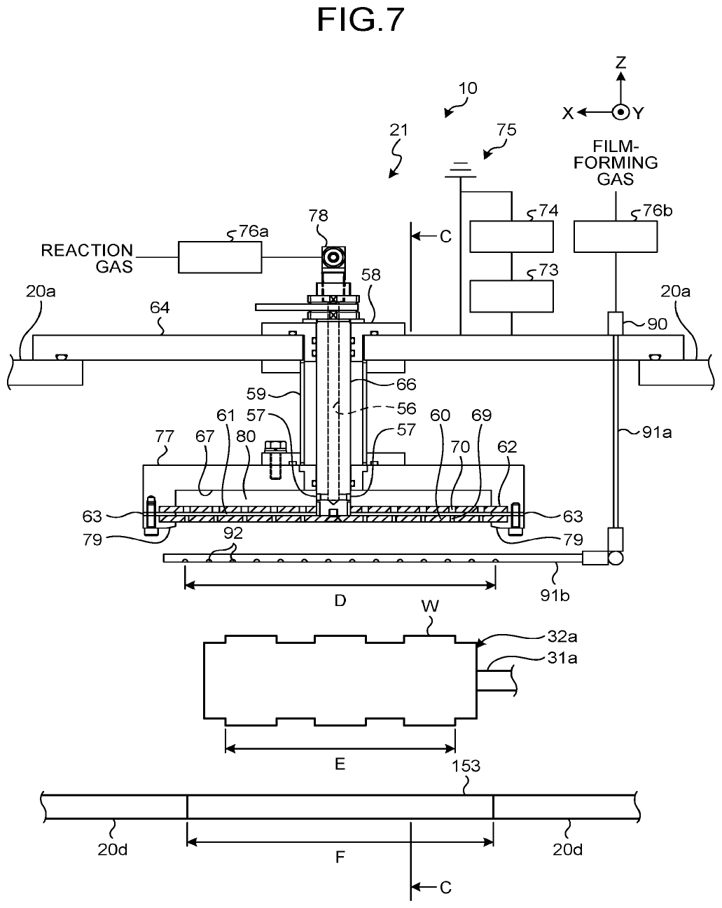

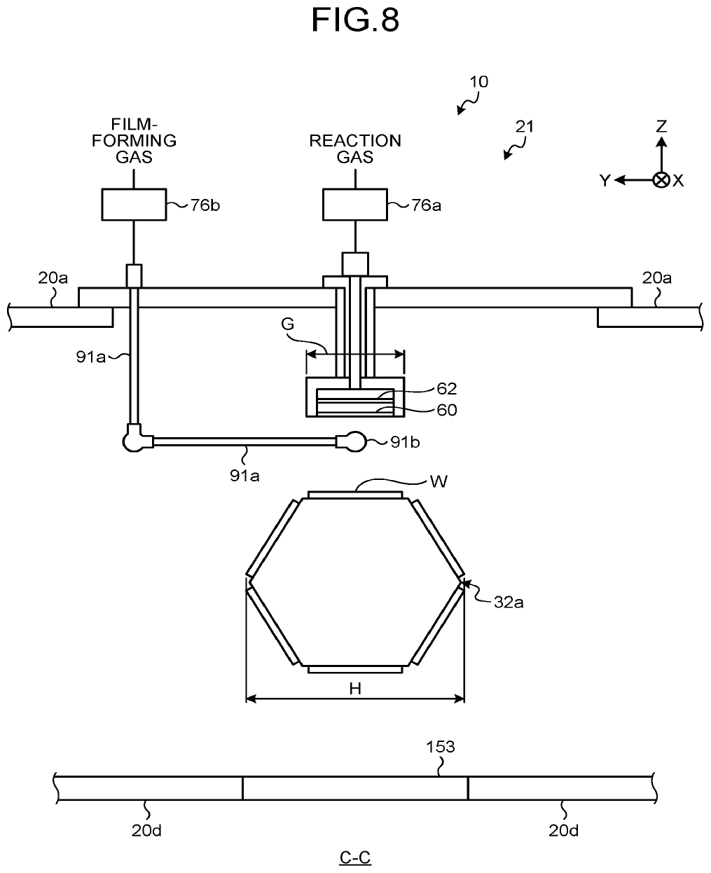

A configuration of the plasma treatment apparatus 21 will be described with reference to FIGS. 7 and 8. FIG. 7 is a first cross-sectional view illustrating an example of the configuration of the plasma treatment apparatus. FIG. 8 is a second cross-sectional view illustrating an example of the configuration of the plasma treatment apparatus.

The plasma treatment apparatus 21 includes a gas supply pipe 66 for supplying the reaction gas such as argon used for generating a plasma gas, and a pair of plate-shaped conductors 60 and 62 for generating the plasma gas from the reaction gas supplied from the gas supply pipe 66 by a high-frequency voltage. As the reaction gas, for example, oxygen, argon, nitrogen, or the like is used alone or in a mixed state.

The gas supply pipe 66 penetrates, in a thickness direction, a support plate 64 fixed to the upper wall surface 20a of the chamber 20, and is attached to the support plate 64 by a gas supply pipe attachment member 58. A gas flow path 56 along an extending direction of the gas supply pipe 66 is formed inside the gas supply pipe 66, and the reaction gas is supplied from the outside of the chamber 20 into the chamber 20 through the gas flow path 56. Note that a gas supply part 78 that supplies the reaction gas to the gas supply pipe 66 is connected to an end of the gas supply pipe 66 on an outer side of the support plate 64 (outer side of the chamber 20), and a gas supply hole 57 that is a hole for introducing the reaction gas flowing through the gas flow path 56 into the chamber 20 is formed at an end on the other side of the gas supply pipe 66 (inner side of the chamber 20). The reaction gas is supplied to the gas supply part 78 through a mass flow controller (MFC) 76a that has a function to control a flow rate in a mass flowmeter.

Each of the pair of plate-shaped conductors 60 and 62 is formed in a flat plate shape, and is formed by arranging a metal plate such as aluminum or other conductor plates in parallel. The plate-shaped conductors 60 and 62 are supported by a support plate 77. The support plate 77 is formed of, for example, an insulating material such as glass or ceramic. The support plate 77 is formed in a shape in which a convex portion is formed over an entire periphery near an outer periphery on a side of the support plate 64. In other words, the support plate 77 is formed in a plate-shaped shape in which a recess 67 concaved along the outer periphery of the support plate 77 is formed inside the chamber 20. Note that the pair of plate-shaped conductors 60 and 62 is an example of an electrode in the present disclosure.

The support plate 77 is supported by a support member 59. The support member 59 includes a cylindrical member and attachment members located at both ends of the cylindrical member. An end of the support member 59 on the Z-axis positive side is attached to the support plate 64, and an end on the Z-axis negative side is attached to the support plate 77.

The gas supply pipe 66 penetrating the support plate 64 passes through an inside of the support member 59 having cylindrical shape, extends to a position of the support plate 77, and penetrates the support plate 77. The gas supply hole 57 formed in the gas supply pipe 66 is disposed in a portion of the support plate 77 where the recess 67 is formed.

The pair of plate-shaped conductors 60 and 62 is disposed on a side of the support plate 77 where the recess 67 is formed, and covers the recess 67. At this time, a spacer 63 is disposed in the vicinity of the outer periphery between the pair of plate-shaped conductors 60 and 62 so that the pair of plate-shaped conductors 60 and 62 are overlaid with the spacer 63 interposed therebetween. The pair of plate-shaped conductors 60 and 62 is disposed apart from each other in a portion other than the spacer 63 to form a gap portion 61 between the plate-shaped conductors 60 and 62. A length of the gap portion 61 is preferably set as appropriate according to a frequency of the reaction gas introduced in the plasma treatment apparatus 21 or power supplied, the size of the electrode, and the like, and is, for example, about 3 mm to 12 mm.

The pair of plate-shaped conductors 60 and 62 is held by a holder 79 which is a member for holding the plate-shaped conductors 60 and 62 in a state where the pair of plate-shaped conductors 60 and 62 are overlaid with each other with the spacer 63 interposed therebetween. In other words, the holder 79 is disposed on an opposite side of the side where the support plate 77 is located in the plate-shaped conductors 60 and 62, and is attached to the support plate 77 in a state where the plate-shaped conductors 60 and 62 are interposed between the holder 79 and the support plate 77.

The pair of plate-shaped conductors 60 and 62 is disposed so as to cover the recess 67 in the support plate 77 in this manner, and a space is formed between the recess 67 of the support plate 77 and the plate-shaped conductors 60 and 62 in a state where the pair of plate-shaped conductors 60 and 62 is held by the holder 79.

When the plate-shaped conductor 62 of the pair of plate-shaped conductors 60 and 62 is disposed on the side of the support plate 77 and the plate-shaped conductor 60 is disposed on the side of the holder 79, the space is defined by the recess 67 of the support plate 77 and the plate-shaped conductor 62. The space formed in this way is formed as a gas introduction part 80 into which the reaction gas supplied by the gas supply pipe 66 is introduced. The gas supply hole 57 of the gas supply pipe 66 is located in the gas introduction part 80 and is opened toward the gas introduction part 80.

A large number of through holes 69 and 70 penetrating in the thickness direction are formed in the pair of plate-shaped conductors 60 and 62, respectively. In other words, in the plate-shaped conductor 62 located on the inflow side of the reaction gas supplied by the gas supply pipe 66, a plurality of through holes 70 is formed at predetermined intervals in matrix when viewed in the thickness direction of the plate-shaped conductor 62. In the plate-shaped conductor 60 located on the outflow side of the reaction gas supplied by the gas supply pipe 66, a plurality of through holes 69 is formed at predetermined intervals in matrix when viewed in the thickness direction of the plate-shaped conductor 60.

The through holes 69 in the plate-shaped conductor 60 and the through holes 70 in the plate-shaped conductor 62 are cylindrical holes, and both the through holes 69 and 70 are coaxially arranged. In other words, the through holes 69 in the plate-shaped conductor 60 and the through holes 70 in the plate-shaped conductor 62 are arranged at positions where the centers of the through holes are aligned. Among these, the through holes 69 in the plate-shaped conductor 60 are smaller in diameter than the through holes 70 in the plate-shaped conductor 62 on the inflow side of the reaction gas. As described above, the plurality of through holes 69 and 70 is formed in the pair of plate-shaped conductors 60 and 62 to form a hollow electrode structure, and the generated plasma gas flows at high density through the plurality of through holes 69 and

The gap portion 61 is interposed between the plate-shaped conductors 60 and 62 in parallel, and the gap portion 61 functions as a capacitor having electrostatic capacitance. A conductive part (not illustrated) is formed on the support plate 77 and the plate-shaped conductors 60 and 62 by a conductive member, and the support plate 77 is grounded 75 and the plate-shaped conductor 62 is also grounded 75 by the conductive part. In addition, one end portion of a high-frequency power source (RF) 74 is grounded 75, and the other end portion of the high-frequency power source 74 is electrically connected to the plate-shaped conductor 60 via a matching box (MB) 73 for adjusting capacitance and the like to match with plasma. Therefore, when the high-frequency power source 74 is operated, a potential of the plate-shaped conductor 60 swings positively and negatively at a predetermined frequency such as 13.56 MHZ.

The plasma gas generated flows out from the through holes 70. Then, on the Z-axis negative side of the through holes 70, the plasma gas flowing out reacts with the film-forming gas sprayed in the Z-axis negative direction from a plurality of gas supply holes 92 formed in a gas supply pipe 91b parallel, i.e., extending along the X-axis, to the plate-shaped conductors 60 and 62.

The film-forming gas is introduced into the chamber 20 from a port 90 via a mass flow controller (MFC) 76b. The film-forming gas is supplied by a gas supply pipe 91a extending along the Z axis and the gas supply pipe 91b extending along the X axis.

As the film-forming gas, a substance corresponding to the surface treatment performed by the surface treatment apparatus 10 is used. For example, methane, acetylene, butadiene, titanium tetraisopropoxide (TTIP), hexamethyldisiloxane (HMDSO), tetraethoxysilane (TEOS), hexamethyldisilazane (HMDS), tetramethylsilane (TMS), and the like are used. Surface treatment such as film formation and cleaning of the workpiece W in the chamber 20 is performed by the precursor generated by reaction between the plasma gas and the film formation gas.

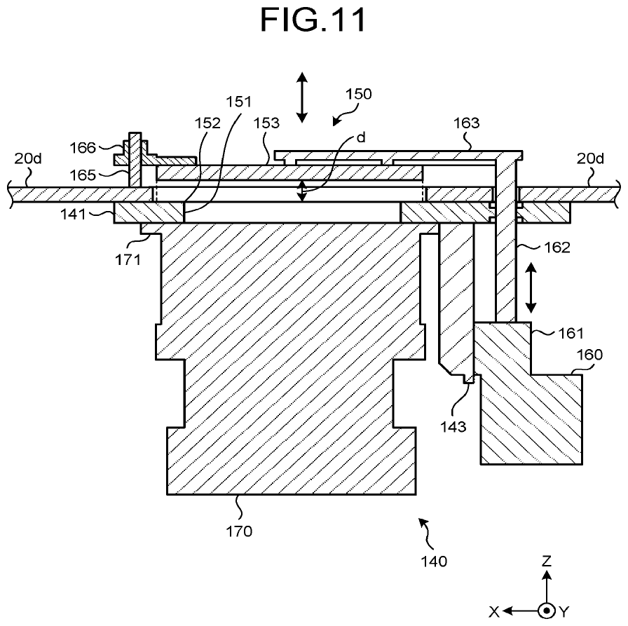

As illustrated in FIG. 7, a range of the plurality of gas supply holes 92 formed in the gas supply pipe 91b and a lifting valve 153 serving as a gas outlet when the gas in the chamber is discharged to the outside of the chamber are at substantially the same position in the X-axis direction. Furthermore, a gas supply length D, which is a length of an area where the plurality of gas supply holes 92 are formed in the gas supply pipe 91b, is substantially equal to an exhaust port length F, which is a length of the lifting valve 153 in the X-axis direction. An action of the lifting valve 153 will be described later in detail (see FIGS. 10 and 11).

Then, the workpiece placement part 32a on which the workpiece W is placed is positioned within the area of the plurality of gas supply holes 92. A placement length E, which is a length of the workpiece placement part 32a in the X-axis direction, is 90% or less of the gas supply length D or the exhaust port length F. As a result, turbulence of gas flow in the chamber can be reduced.

FIG. 8 is a cross-sectional view obtained by cutting FIG. 7 along a cutting line C-C. As illustrated in FIG. 8, a length along the Y axis of the electrodes formed by the pair of plate-shaped conductors 60 and 62, i.e., an electrode length G illustrated in FIG. 8, is about 10% to 50% with respect to a projection length H that is a length obtained by projecting the workpiece placement part 32a to the electrode. Note that, since the projection length H changes according to the rotation angle of the workpiece placement part 32a, the projection length H may be any of a maximum value, a minimum value, and an average value obtained by projecting the workpiece placement part 32a to the electrode.

In other words, since the workpiece W placed on the workpiece placement part 32a rotates about the rotating shaft 31a (see FIG. 2) along the X-axis, the electrode length G can be shortened as compared with the case of forming a film on the workpiece W that does not rotate. When the electrode length G is shortened, a discharge space volume of the electrode is reduced. As a result, time until pressure in a discharge space becomes constant is shortened. Then, time until the generated plasma is stabilized is shortened. In addition, even when the electrode length G is shortened, discharge power per unit area increases by increasing the number of the through holes 69 and 70 formed in the electrodes, and thus, as long as the power applied to the electrodes is the same, a film formation speed does not change. Therefore, a film can be formed on the surface of the workpiece W in a short time.

In addition, in the plasma treatment apparatus 21 included in the surface treatment apparatus 10, the precursor generated by reacting the plasma-converted reaction gas with the film-forming gas is sprayed onto the surface of the workpiece W, and then discharged from the lifting valve 153 installed at a position facing the electrode across the workpiece placement part 32a by the operation of the pump unit 140 (see FIG. 10). Accordingly, by matching the inflow direction and the outflow direction of the gas and shortening the electrode length G in the rotating direction of the workpiece placement part 32a, a flow speed of the gas on the surface of the workpiece W can be made substantially constant. As a result, a film with uniform film thickness is formed on the surface of the workpiece W.

### [6. Configuration of Sputtering Apparatus]

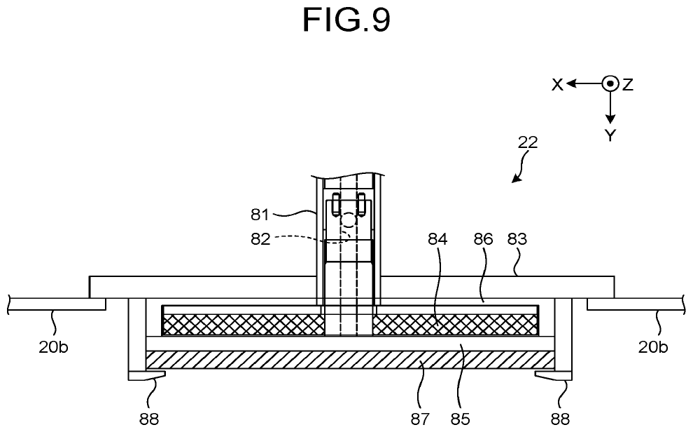

A configuration of the sputtering apparatus 22 will be described with reference to FIG. 9. FIG. 9 is a cross-sectional view illustrating an example of a configuration of a sputtering apparatus. Since the sputtering apparatuses 22 and 23 have the same configuration, only the sputtering apparatus 22 will be described here.

The sputtering apparatus 22 includes a cooling water pipe 81 through which cooling water flows, a magnet 84 that generates a magnetic field, a target 87 that is supplied from the gas supply apparatus 54 (see FIG. 1) inside the magnetic field generated by the magnet 84 and ionizes and collides an inert gas (e.g., argon) flowing in from a gas inflow part (not illustrated) to eject atoms to be used for film formation, a cooling jacket 85 that cools the target 87, and a support plate 83 that supports the magnet 84, the target 87, and the cooling jacket 85. The cooling water pipe 81 penetrates the support plate 83 fixed to the side wall surface 20b of the chamber 20. The target 87 is, for example, a copper plate, and copper atoms ejected from the target 87 are brought into close contact with the surface of the workpiece W to form a thin copper film on the surface of the workpiece W.

A cooling water path 82 along an extending direction of the cooling water pipe 81 is formed inside the cooling water pipe 81. Although not illustrated in FIG. 9, the cooling water path 82 includes a water path for supplying cooling water for cooling from the outside of the chamber 20 to the cooling jacket 85, and a water path for discharging the cooling water used for cooling from the cooling jacket 85 to the outside of the chamber 20. In this manner, the cooling water pipe 81 circulates the cooling water between the outside of the chamber 20 and the cooling jacket 85 disposed in the chamber 20. An inflow path and a discharge path (not illustrated in FIG. 8) of the cooling water are connected to an end of the cooling water pipe 81 on the outer side of the chamber 20. On the other hand, an end on the other end side (inside the chamber 20) of the cooling water pipe 81 is connected to the cooling jacket 85. A cooling water flow path is formed inside the cooling jacket 85, and the cooling water flows. As a result, the cooling water circulates between the outside of the chamber 20 and the cooling jacket 85. The cooling water is supplied from the cooling apparatus 51 (see FIG. 1).

The support plate 83 supports the magnet 84, the cooling jacket 85, and the target 87 in an overlapping state. Specifically, the support plate 83, the magnet 84, the cooling jacket 85, and the target 87 are all formed in a plate shape, and the support plate 83 has a larger shape in plan view than the magnet 84, the cooling jacket 85, and the target 87. Therefore, the magnet 84, the cooling jacket 85, and the target 87 are held by the support plate 83 by supporting the outer periphery of the target 87 by a holder 88 in a state where the magnet 84, the cooling jacket 85, and the target 87 are stacked in this order from the side of the support plate 83.

At this time, an insulating material 86 is disposed between the support plate 83 and the magnet 84, and the insulating material 86 is also disposed on an outer peripheral portion of the magnet 84 in plan view. In other words, the insulating material 86 is disposed between the support plate 83 and the magnet 84 and between the magnet 84 and the holder 88. Therefore, the magnet 84 is held by the support plate 83 and the holder 88 via the insulating material 86.

The sputtering apparatus 22 performs so-called sputtering to form a thin film on the surface of the workpiece W. When the sputtering apparatus 22 performs sputtering, the chamber 20 is depressurized by the exhaust apparatus 50 (see FIG. 1), and then gas used for sputtering is caused to flow into the chamber 20 from the gas supply apparatus 54 (see FIG. 1). Then, the gas in the chamber 20 is ionized by a magnetic field generated by the magnet 84 of the sputtering apparatus 22, and ions collide with the target 87. As a result, atoms of the target 87 are ejected from the surface of the target 87.

For example, when aluminum is used for the target 87, the target 87 ejects atoms of aluminum by making ions of gas ionized in the vicinity of the target 87 collide with the target 87. The atoms of aluminum ejected from the target 87 are directed in the Y-axis positive direction. Since the workpiece W is located at a position facing the surface of the target 87 in the chamber 20, the atoms of aluminum ejected from the target 87 move toward the workpiece W to be in close contact with the workpiece W, and are deposited on the surface of the workpiece W. As a result, a thin film according to the substance for forming the target 87 is formed on the surface of the workpiece W.

### [7. Configuration of Pump Unit]

A configuration of the pump unit 140 will be described with reference to FIGS. 10 and 11. FIG. 10 is a side view illustrating an example of the pump unit. FIG. 11 is an XZ cross-sectional view of FIG. 10, illustrating a state in which the pump unit exhausts air in the chamber.

The pump unit 140 is attached to the bottom surface 20d of the chamber 20, i.e., at a position different from the position where the plasma treatment apparatus 21 and the sputtering apparatus 23 are installed. The pump unit 140 adjusts the pressure in the chamber 20 and exhausts the gas filled in the chamber 20 by the operation of the plasma treatment apparatus 21 and the sputtering apparatuses 22 and 23. The pump unit 140 is an example of an exhaust device in the present disclosure.

The pump unit 140 includes a flow rate regulating valve 150 and a turbo molecular pump 170 illustrated in FIG. 10.

As illustrated in FIG. 11, the flow rate regulating valve 150 includes a flow path 151 through which a fluid flows, the lifting valve 153 that opens and closes an opening 152 formed at one end of the flow path 151, and a servo actuator 160 that performs an opening/closing operation of the lifting valve 153. The turbo molecular pump 170 is a pump that sucks fluid flowing through the flow path 151 of the flow rate regulating valve 150. The pump unit 140 reduces the pressure in the chamber 20 to a desired pressure by adjusting the flow rate of the fluid sucked by the turbo molecular pump 170 with the flow rate regulating valve 150.

The pump unit 140 is installed on the bottom of the chamber 20 by attaching a pump flange 171 formed at an upper end of the turbo molecular pump 170 to an attachment flange 141 installed on the bottom surface 20d of the chamber 20. In a state where the attachment flange 141 is attached to the bottom surface of the chamber 20, the opening 152 of the flow path 151 is open to the inside of the chamber 20, and the flow path 151 communicates with the inside of the chamber 20.

The flow rate regulating valve 150 includes the lifting valve 153 disposed in the chamber 20, and the servo actuator 160 that is a driving device for moving the lifting valve 153 in the Z-axis direction in the chamber 20. The lifting valve 153 moves in the Z-axis direction in the chamber 20 to adjust the flow rate of the fluid sucked by the turbo molecular pump 170. The opening/closing operation of the lifting valve 153 is guided by a guide engagement portion 166 attached to the lifting valve 153 moving up and down along a valve guide 165. The servo actuator 160 is disposed on a surface side on which the turbo molecular pump 170 is mounted in the attachment flange 141, and is supported by a drive device support 143.

In addition, the flow rate regulating valve 150 includes a lifting shaft 162 to which the lifting valve 153 is connected via a connector 163, and a worm jack 161 that transmits power generated by the servo actuator 160 to the lifting shaft 162 to move the lifting shaft 162 in the Z-axis direction. A vacuum gauge (not illustrated) is attached to the chamber 20, and the pressure inside the chamber 20 is measured by the vacuum gauge. The servo actuator 160 operates based on the measurement value of the vacuum gauge to move the lifting valve 153 in the Z-axis direction and adjust the flow rate of the fluid to be sucked by the turbo molecular pump 170.

More specifically, the lifting shaft 162, the connector 163, and the lifting valve 153 integrally move along the Z-axis direction to change a distance d (see FIG. 11) in the Z-axis direction from the opening 152, thereby opening and closing the opening 152. In other words, the lifting valve 153 closes the opening 152 by moving in the Z-axis negative direction to cover the entire area of the opening 152. On the other hand, the lifting valve 153 moves in the Z-axis positive direction to open the opening 152.

### [8. Specific Description of Surface Treatment]

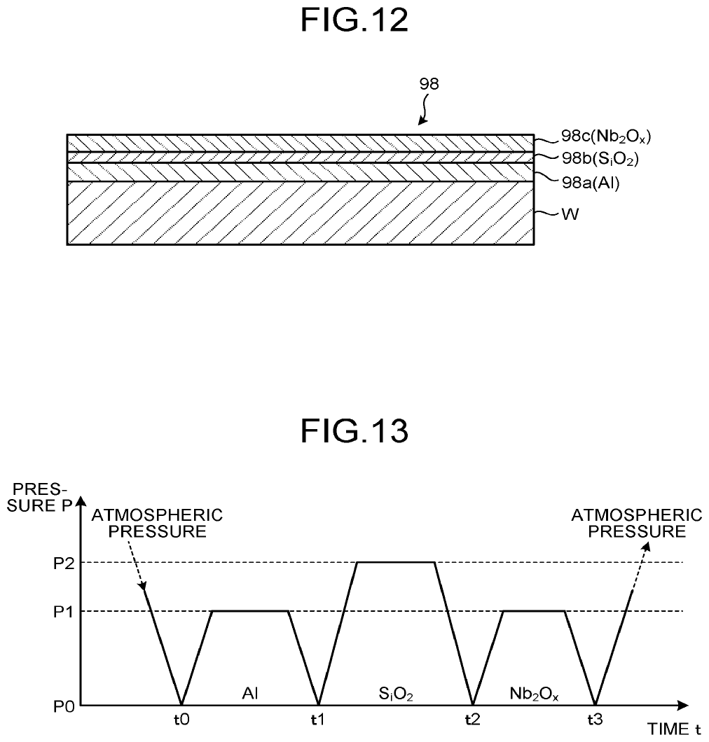

A specific example of the surface treatment performed by the surface treatment apparatus 10 according to the present embodiment will be described with reference to FIGS. 12 and 13. FIG. 12 is a diagram illustrating an example of the surface treatment applied to the workpiece by the surface treatment apparatus. FIG. 13 is a diagram illustrating an example of a pressure change in the chamber when the surface treatment apparatus performs the surface treatment on the workpiece.

In the present embodiment, the surface treatment apparatus 10 forms, for example, a mirror 98, which is an example of an optical component, on one surface of the workpiece W. For example, the mirror 98 has a substantially constant reflectance over the entire visible light region (400 nm to 800 nm).

First, the surface treatment apparatus 10 operates the sputtering apparatus 22 to generate an Al layer 98a that is a thin film of aluminum (Al) on the surface of the workpiece W. At this time, aluminum is used for the target 87 of the sputtering apparatus 22. Then, as illustrated in FIG. 13, in the chamber 20, aluminum is sputtered in a state where the pressure is increased from a state where the pressure is reduced to pressure P0 (e.g., 10-2 Pa to 10-3 Pa) at time t0 to pressure P1 by allowing gas to flow in. The pressure P1 is, for example, 20 Pa. After completion of the sputtering, the pressure in the chamber 20 is reduced again to the pressure P0 at time t1. In FIG. 13, the vertical axis represents pressure P, and a lower side represents a depressurized state.

While the sputtering is being performed, the surface treatment apparatus 10 rotates the rotating shaft 31a to form the Al layer 98a in the uniform manner on the surface of the workpiece W placed on the workpiece placement part 32a. The rotational speed of the rotating shaft 31a is set according to the type of the workpiece W, the conditions for forming the Al layer 98a, and the like.

Next, the surface treatment apparatus 10 operates the plasma treatment apparatus 21 to generate an SiO₂ layer 98b on the surface of the Al layer 89a of the workpiece W. At this time, the SiO₂ layer 98b (polymerized film) is formed in a state where the inside of the chamber 20 is pressurized to pressure P2 by allowing gas to flow in from the state where the inside of the chamber 20 is reduced to the pressure P0 at the time t1. The pressure P2 is set to pressure higher than the pressure P1. The pressure P2 is, for example, 30 Pa. After the formation of the SiO₂ layer 98b, the pressure in the chamber 20 is reduced to the pressure P0 again at time t2.

While the SiO₂ layer 98b is being generated, the surface treatment apparatus 10 rotates the rotating shaft 31a to form the SiO₂ layer 98b in the uniform manner on the surface of the workpiece W placed on the workpiece placement part 32a. The rotation speed of the rotating shaft 31a is set according to the type of the workpiece W, the conditions for generating the SiO₂ layer 98b, and the like. In order to form the SiO₂ layer 98b, for example, water vapor and silane-based gas flow into the chamber 20 as the film-forming gas.

Next, the surface treatment apparatus 10 operates the sputtering apparatus 23 to form an Nb₂O_{X} layer 98c that is a thin film of niobium oxide (Nb₂O_{X}) on the surface of the SiO₂ layer 98b of the workpiece W. At this time, niobium oxide is used for the target 87 of the sputtering apparatus 23. Then, Nb₂O_{X} is sputtered in a state where the inside of the chamber 20 is pressurized to the pressure P1 by allowing the gas to flow in from the state where the inside of the chamber 20 is reduced to the pressure P0 at the time t2. After completion of the sputtering, the pressure in the chamber 20 is reduced again to the pressure P0 at time t3.

During the sputtering, the surface treatment apparatus 10 rotates the rotating shaft 31a to form the Nb₂O_{X} layer 89c in the uniform manner on the surface of the workpiece W placed on the workpiece placement part 32a. The rotation speed of the rotating shaft 31a is set according to the type of the workpiece W, the conditions for generating the Nb₂O_{X} layer 98c, and the like.

Before the start of the surface treatment of the workpiece W and after the completion of the surface treatment, the chamber 20 is opened so that the pressure in the chamber 20 is made equal to the atmospheric pressure.

The order of forming the Al layer 98a, the SiO₂ layer 98b, and the Nb₂O_{X} layer 98c by the surface treatment apparatus 10 is not limited to the above example. In other words, after the SiO₂ layer 98b is formed on the surface of the workpiece W, the Al layer 98a may be formed on the surface of the SiO₂ layer 98b, and the Nb₂O_{X} layer 98c may be formed on the surface of the Al layer 98a.

Alternatively, after the Al layer 98a, the SiO₂ layer 98b, and the Nb₂O_{X} layer 98c are formed, the SiO₂ layer 98b and the Nb₂O_{X} layer 98c may be further formed on the Nb₂O_{X} layer 98c.

[9. Processing Flow of Surface Treatment apparatus]

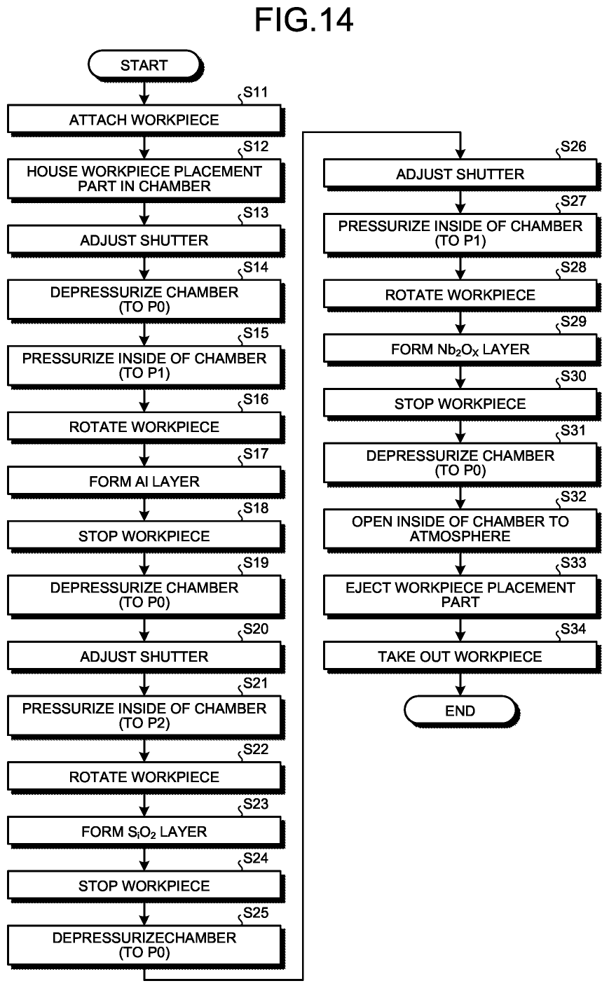

A processing flow performed by the surface treatment apparatus 10 according to the present embodiment will be described with reference to FIG. 14. FIG. 14 is a flowchart illustrating an example of the processing flow performed when the surface treatment apparatus performs the surface treatment on the workpiece.

First, the workpiece W is attached to the workpiece placement part 32a (Step S11).

The workpiece conveyance part 40 houses the workpiece placement part 32a in the chamber 20 (Step S12). After Step S12 is completed, the workpiece W to be subjected to the next surface treatment may be attached to the workpiece placement part 32b outside the chamber 20 while the surface treatment apparatus 10 performs the surface treatment.

In accordance with an operation instruction from the operation panel 55, the shutter 26b covering the surface of the sputtering apparatus 22 is stored in the shutter storage part 25, the shutter 26c covering the surface of the sputtering apparatus 23 and the shutter 26a covering the surface of the plasma treatment apparatus 21 are pulled out from the shutter storage part 25, and the electrodes of the surface treatment device other than that of the sputtering apparatus 22 are shielded (Step S13).

The exhaust apparatus 50 depressurizes the chamber 20 to the pressure P0 (Step S14).

The gas supply apparatus 54 supplies gas into the chamber and pressurizes the inside of the chamber 20 to the pressure P1 (Step S15).

The workpiece placement part 32a is rotated according to the operation instruction from the operation panel 55. As a result, the workpiece W rotates (Step S16).

The sputtering apparatus 22 forms the Al layer 89a on the surface of the workpiece W (Step S17).

The rotation of the workpiece placement part 32a is stopped according to the operation instruction from the operation panel 55. As a result, the workpiece W stops (Step S18).

The exhaust apparatus 50 depressurizes the chamber 20 to the pressure P0 (Step S19).

By the operation of the operation panel 55, the shutter 26a covering the surface of the plasma treatment apparatus 21 is stored in the shutter storage part 25, and the shutter 26b covering the surface of the sputtering apparatus 22 and the shutter 26c covering the surface of the sputtering apparatus 23 are pulled out from the shutter storage part 25 to shield the electrodes of the surface treatment device other than that of the plasma treatment apparatus 21 (Step S20).

The gas supply apparatus 54 supplies gas into the chamber and pressurizes the inside of the chamber 20 to the pressure P2 (Step S21).

The workpiece placement part 32a is rotated according to the operation instruction from the operation panel 55. As a result, the workpiece W rotates (Step S22).

The plasma treatment apparatus 21 generates the SiO₂ layer 98b on the surface of the Al layer 98a (Step S23).

The rotation of the workpiece placement part 32a is stopped according to the operation instruction from the operation panel 55. As a result, the workpiece W stops (Step S24).

The exhaust apparatus 50 depressurizes the chamber 20 to the pressure P0 (Step S25).

According to the operation instruction from the operation panel 55, the shutter 26c covering the surface of the sputtering apparatus 23 is stored in the shutter storage part 25, the shutter 26b covering the surface of the sputtering apparatus 22 and the shutter 26a covering the surface of the plasma treatment apparatus 21 are pulled out from the shutter storage part 25, and the electrodes of the surface treatment device other than that of the sputtering apparatus 23 are shielded (Step S26).

The gas supply apparatus 54 supplies gas into the chamber and pressurizes the inside of the chamber to the pressure P1 (Step S27).

The workpiece placement part 32a is rotated according to the operation instruction from the operation panel 55. As a result, the workpiece W rotates (Step S28).

The sputtering apparatus 23 forms the Nb₂O_{X} layer 98c on the surface of the SiO₂ layer 98b (Step S29).

The rotation of the workpiece placement part 32a is stopped according to the operation instruction from the operation panel 55. As a result, the workpiece W stops (Step S30).

The exhaust apparatus 50 reduces the pressure inside the chamber 20 to the pressure P0 (Step S31).

According to the operation instruction from the operation panel 55, the lifting valve 153 of the flow rate regulating valve 150 is opened to take air around the chamber 20 into the chamber 20, and the inside of the chamber is opened to the atmosphere (Step S32).

The workpiece conveyance part 40 ejects the workpiece placement part 32a from the chamber 20 (Step S33).

The workpiece W subjected to the surface treatment is taken out from the workpiece placement part 32a (Step S34).

Although not illustrated in the flowchart in FIG. 14, the workpiece placement part 32b may be directed toward the chamber 20 by rotating the workpiece mounting part rotating shaft 35, and the above-described steps may be repeated.

In addition, a series of steps described above may be executed based on an operator's instruction or may be automatically executed according to a sequence created in advance.

As described above, the surface treatment apparatus 10 according to the present embodiment includes the chamber 20 (housing unit) that houses at least one workpiece W, the workpiece placement parts 32a and 32b (placement device) that include the rotating shaft 31a extending in the horizontal direction and place the workpiece W such that the surface of the workpiece W is orthogonal to the normal direction of the outer peripheral surfaces of the rotating shafts 31a and 31b, and faces outward substantially, the motors 36a and 36b (first rotating device) that rotate the workpiece placement parts 32a and 32b in a predetermined rotation pattern around the rotating shafts 31a and 31b in a state where the workpiece placement parts 32a and 32b are housed in the chamber 20, the plasma treatment apparatus 21 (surface treatment device) that extends inside the chamber 20 and in parallel with the rotating shafts 31a and 31b and performs at least one type of surface treatment by supplying gas to the surface of the workpiece W, and the pump unit 140 (exhaust device) that is provided at the position different from the position where the plasma treatment apparatus 21 is provided inside the chamber 20, adjusts the pressure inside the chamber 20, and exhausts the gas inside the chamber 20. Therefore, it is possible to provide the surface treatment apparatus suitable for performing the surface treatment of a small to medium amount of material. Furthermore, since the inflow direction and the outflow direction of the gas coincide with each other, the flow speed of the gas on the surface of the workpiece W can be made substantially constant. As a result, a film with uniform film thickness can be formed on the surface of the workpiece W.

In the surface treatment apparatus 10 of the present embodiment, the pump unit 140 (exhaust device) is horizontally provided in the lower part, i.e., the bottom surface 20d, of the chamber 20 (housing unit). Therefore, the inflow direction of the reaction gas sprayed onto the surface of the workpiece W can be matched with the discharge direction of the reaction gas. As a result, the flow speed of the gas on the surface of the workpiece W can be made substantially constant. Therefore, when the pump unit 140 exhausts air inside the chamber 20, the surface of the workpiece W is uniformly affected by the exhausted gas, so that uniformity of the film generated on the surface of the workpiece W can be maintained.

Still more, in the surface treatment apparatus 10 of the present embodiment, the workpiece placement parts 32a and 32b (placement device) include bases 33a and 33b (sealing members) that seal the chamber 20 when the workpiece placement parts 32a and 32b are housed in the chamber 20. Therefore, housing of the workpiece W in the chamber 20 and sealing of the chamber 20 can be successively performed by a series of operations.

The surface treatment apparatus 10 according to the present embodiment further includes a workpiece mounting part rotating shaft 35 (selection device) that is provided with a plurality of placement device (workpiece placement parts 32a and 32b) to select one placement device to be housed in the chamber 20 from the plurality of workpiece placement parts 32a and 32b. Therefore, during the surface treatment of the workpiece W, the workpiece W to be treated next can be attached to the workpiece placement part located outside the chamber 20. Therefore, time can be effectively used.

The surface treatment apparatus 10 according to the present embodiment further includes the workpiece mounting part rotating shaft 35 (selection device) that is provided with the motor 34 (second rotating device) that rotates any one of the plurality of workpiece placement parts 32a and 32b to a position facing the opening 20f (housing port) of the chamber 20. Thus, the workpiece placement part 32a and the workpiece placement part 32b can be easily replaced.

The surface treatment apparatus 10 according to the present embodiment further includes the workpiece conveyance part 40 (conveyance device) that conveys the workpieces W placed on the workpiece placement parts 32a and 32b (placement device) in the axial direction of the rotating shaft 31a so that the workpieces W are housed in the chamber 20 (housing unit) or carried out of the chamber 20. Therefore, housing of the workpieces W in the chamber 20 and ejecting the workpieces W from the chamber 20 can be automated.

Further, in the surface treatment apparatus 10 according to the present embodiment, the surface treatment device is the plasma treatment apparatus 21 that performs the surface treatment of the workpiece W by supplying the reaction gas to a pair of plate-shaped conductors 60 and 62 (electrodes) extending inside the chamber 20 (housing unit) and in parallel with the rotating shaft 31a of the workpiece placement part 32a (placement device) to plasma-convert the reaction gas, and spraying the precursor generated by reaction of the plasma-converted reaction gas with the film-forming gas, onto the workpiece W. Therefore, for example, by generating a functional group on the surface of the workpiece W, adhesion of the thin film formed in a subsequent step can be improved.

Further, in the surface treatment apparatus 10 according to the present embodiment, the plasma treatment apparatus 21 is provided on the upper wall surface 20a (upper inner wall surface) of the workpiece placement part 32a (placement device). Therefore, since the film-forming gas uniformly flows from the upper wall surface 20a toward the bottom surface 20d where the exhaust port is provided, the film can be uniformly formed on the workpiece W.

Further, in the surface treatment apparatus 10 according to the present embodiment, the length (electrode length G) of the pair of plate-shaped conductors 60 and 62 (electrodes) in the direction along the rotating direction of the workpiece placement parts 32a and 32b (placement device) is 10% to 50% of the projection length H obtained by projecting the workpiece placement parts 32a and 32b in the direction of the plate-shaped conductors 60 and 62. Thus, since the flow speed of the gas on the surface of the workpiece W can be made substantially constant, a film with uniform film thickness can be formed on the surface of the workpiece W.

Further, in the surface treatment apparatus 10 according to the present embodiment, the surface treatment device is the sputtering apparatus 22 that performs sputtering on the workpiece W. Thus, a desired thin film can be formed on the surface of the workpiece W.

### Second Embodiment

Next, a second embodiment of the present disclosure will be described. A surface treatment apparatus 10a according to the second embodiment includes a plasma treatment apparatus 21a instead of the plasma treatment apparatus 21 included in the surface treatment apparatus 10 described in the first embodiment. Since other components of the surface treatment apparatus 10a are same as those of the surface treatment apparatus 10, only a configuration of the plasma treatment apparatus 21a will be described below.

[10. Configuration of plasma treatment apparatus]

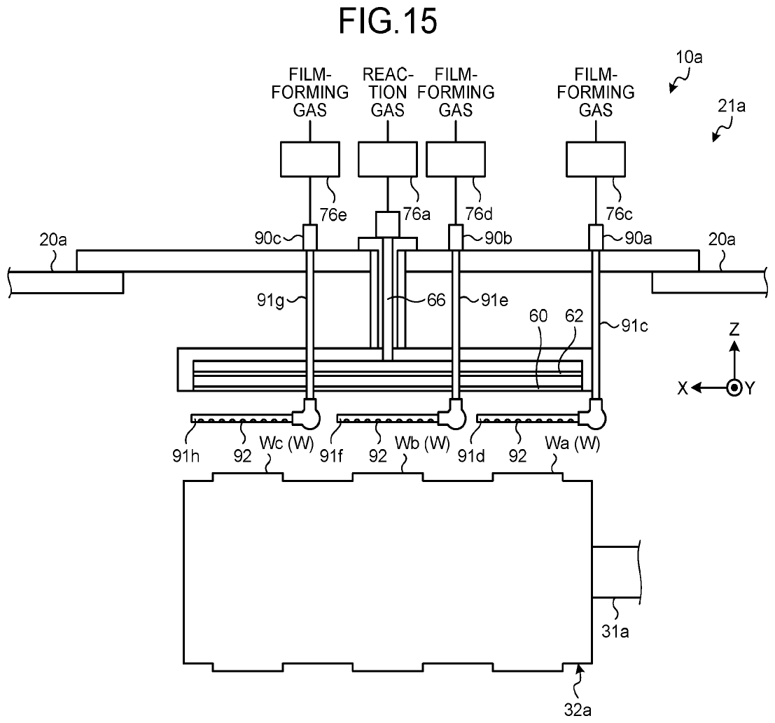

A configuration of the plasma treatment apparatus 21a will be described with reference to FIG. 15. FIG. 15 is an XZ cross-sectional view illustrating an example of a schematic configuration of the plasma treatment apparatus included in the surface treatment apparatus according to the second embodiment.

The plasma treatment apparatus 21a performs different plasma treatment on each of three workpieces W (Wa, Wb, and Wc) placed on each side surface of a regular hexagonal prism forming the workpiece placement part 32a.

The plasma treatment apparatus 21a includes a plurality of (three) gas supply pipes instead of the gas supply pipes 91a and 91b that supply the film-forming gas described in FIG. 7. Specifically, the plasma treatment apparatus 21a includes gas supply pipes 91c and 91d, gas supply pipes 91e and 91f, and gas supply pipes 91g and 91h illustrated in FIG. 15.

The gas supply pipes 91c and 91d are provided between the pair of plate-shaped conductors 60 and 62 and the workpiece Wa. The film-forming gas is supplied to the gas supply pipes 91c and 91d through a port 90a. A supply amount of the film-forming gas is controlled by a mass flow controller 76c.

The gas supply pipe 91c is introduced into the chamber 20 along the Z axis from a position on the Y-axis positive side with respect to the pair of plate-shaped conductors 60 and 62 in the same manner as illustrated in FIG. 8. The gas supply pipe 91c extends in the direction of the pair of plate-shaped conductors 60 and 62 by changing the direction by 90 degrees to the Y-axis negative side. Further, at substantially the center in the Y-axis direction of the pair of plate-shaped conductors 60 and 62, the gas supply pipe 91c changes a direction thereof by 90 degrees to the X-axis positive side, and extends, as the gas supply pipe 91d, in a state where it is substantially parallel to the pair of plate-shaped conductors 60 and 62.

The gas supply pipes 91e and 91f are provided between the pair of plate-shaped conductors 60 and 62 and the workpiece Wb in the same layout as the gas supply pipes 91c and 91d described above. The film-forming gas is supplied to the gas supply pipes 91e and 91f through a port 90b. A supply amount of the film-forming gas is controlled by a mass flow controller 76d.

The gas supply pipes 91g and 91h are provided between the pair of plate-shaped conductors 60 and 62 and the workpiece Wc in the same layout as the gas supply pipes 91c and 91d described above. The film-forming gas is supplied to the gas supply pipes 91g and 91h through a port 90c. A supply amount of the film-forming gas is controlled by a mass flow controller 76e.

As described in the first embodiment, the length (electrode length G (see FIG. 8)) along the Y axis of the electrode formed by the pair of plate-shaped conductors 60 and 62 is about 10% to 50% of the projection length H (see FIG. 8) that is the length obtained by projecting the workpiece placement part 32a to the electrode. Further, it is not always necessary to place three workpieces W to be treated on each side surface of the workpiece placement part 32a. According to an operation instruction from the operation panel 55 (see FIG. 1), the surface treatment apparatus 10a does not supply the film-forming gas from the gas supply pipe corresponding to a position where the workpiece W is not provided.

The plasma treatment apparatus 21a independently sets the amount of the film-forming gas supplied from the gas supply pipes 91c and 91d, the gas supply pipes 91e and 91f, and the gas supply pipes 91g and 91h. Thus, films having different film thicknesses are formed on the surfaces of the workpieces Wa, Wb, and Wc. Still more, the plasma treatment apparatus 21a achieves each film with uniform thickness even when the film thicknesses formed on the workpieces Wa, Wb, and Wc are not equal. The amount of the film-forming gas supplied from each gas supply pipe is set according to the operation instruction from the operation panel 55 (see FIG. 1).

As described above, in the surface treatment apparatus 10a of the second embodiment, the plasma treatment apparatus 21a includes the plurality of gas supply pipes for the film-forming gas, and independently sets the supply amount of the film-forming gas for each of the plurality of workpieces Wa, Wb, and Wc placed along the extending direction of the rotating shaft 31a. Therefore, films having different film thicknesses can be formed on the workpieces Wa, Wb, and Wc placed on the workpiece placement part 32a. Still more, a thickness of each film formed on each of the workpieces Wa, Wb, and Wc can be made uniform.

In the sputtering apparatuses 22 and 23, a set of the magnet 84, the target 87, and the cooling jacket 85 may be installed at positions corresponding to the workpieces Wa, Wb, and Wc, respectively, and sputtering may be performed independently for each of the workpieces Wa, Wb, and Wc.

### [Modification of Second Embodiment]

Next, a modification of the second embodiment of the present disclosure will be described. A surface treatment apparatus 10b (not illustrated) according to the modification of the second embodiment includes a plasma treatment apparatus 21b instead of the plasma treatment apparatus 21 included in the surface treatment apparatus 10 described in the first embodiment. Since other components of the surface treatment apparatus 10b are the same as those of the surface treatment apparatus 10, only a configuration of the plasma treatment apparatus 21b will be described below.

### [11. Configuration of Plasma Treatment Apparatus]

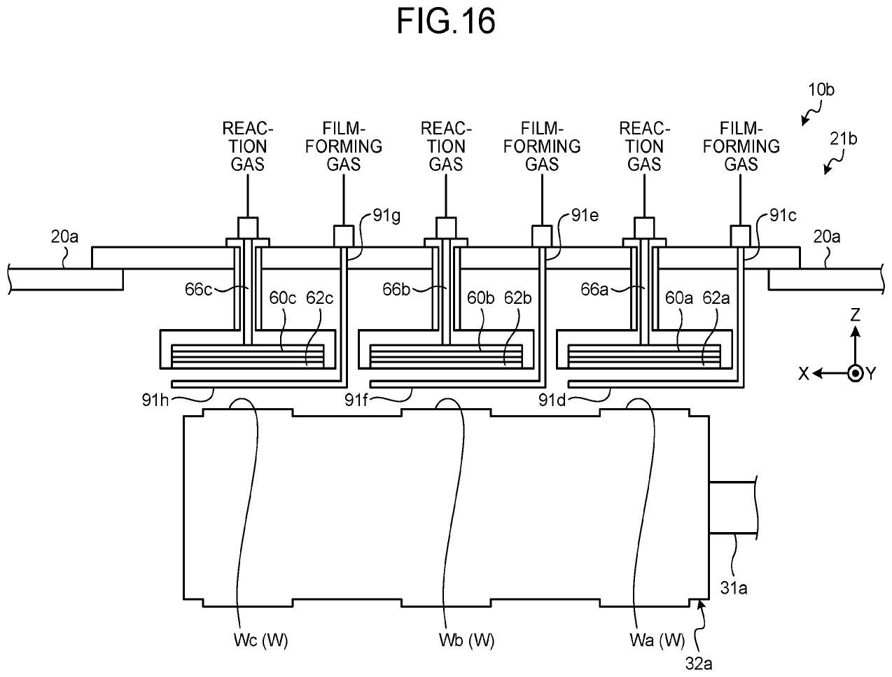

A configuration of the plasma treatment apparatus 21b will be described with reference to FIG. 16. FIG. 16 is an XZ cross-sectional view illustrating an example of a schematic configuration of a plasma treatment apparatus included in a surface treatment apparatus according to the modification of the second embodiment.

The plasma treatment apparatus 21b performs different plasma treatment on each of three workpieces W (Wa, Wb, Wc) placed on each side surface of the regular hexagonal prism forming the workpiece placement part 32a.

The plasma treatment apparatus 21b includes a plurality of (three) gas supply pipes instead of the gas supply pipes 91a and 91b that supply the film-forming gas described in FIG. 7. Specifically, the plasma treatment apparatus 21a includes gas supply pipes 91c and 91d, gas supply pipes 91e and 91f, and gas supply pipes 91g and 91h illustrated in FIG. 16. Note that a cross-sectional view of each gas supply pipe is omitted from a mode illustrated in FIG. 15.

Further, the plasma treatment apparatus 21b includes a plurality (three sets) of electrodes instead of the pair of plate-shaped conductors 60 and 62 (electrodes) described in FIG. 7. Specifically, the plasma treatment apparatus 21b includes a pair of plate-shaped conductors 60a and 62a, a pair of plate-shaped conductors 60b and 62b, and a pair of plate-shaped conductors 60c and 62c illustrated in FIG. 16.

The gas supply pipes 91c and 91d are provided between the pair of plate-shaped conductors 60a and 62a and the workpiece Wa. The film-forming gas is supplied to the gas supply pipes 91c and 91d through a port (not illustrated). A supply amount of the film-forming gas is controlled by a mass flow controller (not illustrated).

The reaction gas is supplied to the pair of plate-shaped conductors 60a and 62a through a gas supply pipe 66a. A supply amount of the reaction gas is controlled by a mass flow controller (not illustrated).

The gas supply pipes 91e and 91f are provided between the pair of plate-shaped conductors 60b and 62b and the workpiece Wb. The film-forming gas is supplied to the gas supply pipes 91e and 91f through a port (not illustrated). A supply amount of the film-forming gas is controlled by a mass flow controller (not illustrated).

The reaction gas is supplied to the pair of plate-shaped conductors 60b and 62b through a gas supply pipe 66b. A supply amount of the reaction gas is controlled by a mass flow controller (not illustrated).

The gas supply pipes 91g and 91h are provided between the pair of plate-shaped conductors 60c and 62c and the workpiece Wc. The film-forming gas is supplied to the gas supply pipes 91g and 91h through a port (not illustrated). A supply amount of the film-forming gas is controlled by a mass flow controller (not illustrated).

The reaction gas is supplied to the pair of plate-shaped conductors 60c and 62c through a gas supply pipe 66c. A supply amount of the reaction gas is controlled by a mass flow controller (not illustrated).

High-frequency power is independently supplied to the pair of plate-shaped conductors 60a and 62a, the pair of plate-shaped conductors 60b and 62b, and the pair of plate-shaped conductors 60c and 62c. Then, the high-frequency power supplied to each plate-shaped conductor reacts with the reaction gas supplied to each plate-shaped conductor to generate plasma gas having different states, for example, plasma gas having a different quantity of charged particles.

As described in the first embodiment, the length along the Y axis of the electrode (electrode length G (see FIG. 8)) formed by each of the pair of plate-shaped conductors 60a and 62a, the pair of plate-shaped conductors 60b and 62b, and the pair of plate-shaped conductors 60c and 62c is about 10% to 50% with respect to the projection length H (see FIG. 8) that is the length obtained by projecting the workpiece placement part 32a to the electrode. Further, it is not always necessary to place three workpieces W to be treated on each side surface of the workpiece placement part 32a. According to the operation instruction from the operation panel 55 (see FIG. 1), the surface treatment apparatus 10b does not supply the film formation gas and the reaction gas from the gas supply pipe corresponding to a position where the workpiece W is not provided.

The plasma treatment apparatus 21b independently sets the amount of the film-forming gas supplied from the gas supply pipes 91c and 91d, the gas supply pipes 91e and 91f, and the gas supply pipes 91g and 91h, and independently sets the high-frequency power to be supplied to the pair of plate-shaped conductors 60a and 62a, the pair of plate-shaped conductors 60b and 62b, and the pair of plate-shaped conductors 60c and 62c. Thus, films having different film thicknesses are formed on the surfaces of the workpieces Wa, Wb, and Wc. Still more, even when the film thicknesses generated on the surfaces of the workpieces Wa, Wb, and Wc are not equal, a thickness of each film is made uniform. The high-frequency power to be supplied to each electrode is set according to the operation instruction from the operation panel 55 (see FIG. 1)

As described above, in the surface treatment apparatus 10b according to the present embodiment, the plasma treatment apparatus 21b includes the plurality of electrodes corresponding to the plurality of workpieces Wa, Wb, and Wc placed along the extending direction of the rotating shaft 31a, and independently sets the high-frequency power to be supplied to the plurality of electrodes. Therefore, films having different film thicknesses can be formed on the workpieces Wa, Wb, and Wc placed on the workpiece placement part 32a. Still more, a thickness of each film formed on each of the workpieces Wa, Wb, and Wc can be made uniform.

Although the embodiments of the present invention have been described above, these embodiments are examples and not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

### EXPLANATIONS OF LETTERS OR NUMERALS

10, 10a, 10b SURFACE TREATMENT APPARATUS
20 CHAMBER (HOUSING UNIT)
20a UPPER WALL SURFACE
20b, 20c, 20e SIDE WALL SURFACE
20d BOTTOM SURFACE
20f OPENING (HOUSING PORT)
21, 21a, 21b PLASMA TREATMENT APPARATUS (SURFACE TREATMENT DEVICE)
22, 23 SPUTTERING APPARATUS (SURFACE TREATMENT DEVICE)
25 SHUTTER STORAGE PART
26a, 26b, 26c SHUTTER (SHIELDING MEMBER)
30, 30a, 30b WORKPIECE MOUNTING PART
31a, 31b ROTATING SHAFT
32a, 32b WORKPIECE PLACEMENT PART (PLACEMENT DEVICE)
33a, 33b BASE (SEALING MEMBER)
34 MOTOR (SECOND ROTATING DEVICE)
35 WORKPIECE MOUNTING PART ROTATING SHAFT (SELECTION DEVICE)
36a, 36b MOTOR (FIRST ROTATING DEVICE)
37a, 37b, 38a, 38b GEAR
39 GROOVE
40 WORKPIECE CONVEYANCE PART (CONVEYANCE DEVICE)
50 EXHAUST APPARATUS
51 COOLING APPARATUS
52 CONTROL APPARATUS
53 POWER SUPPLY APPARATUS
54 GAS SUPPLY APPARATUS
55 OPERATION PANEL
56 GAS FLOW PATH
57, 92 GAS SUPPLY HOLE
58 GAS SUPPLY PIPE ATTACHMENT MEMBER
59 SUPPORT MEMBER
60, 60a, 60b, 60c, 62, 62a, 62b, 62c PLATE-SHAPED CONDUCTOR (ELECTRODE)
61 GAP PORTION
63 SPACER
64, 77, 83 SUPPORT PLATE
66, 66a, 66b, 66c, 91a, 91b, 91c, 91d, 91e, 91f, 91g, 91h GAS SUPPLY PIPE
67 RECESS
69, 70 THROUGH HOLE
73 MATCHING BOX (MB)
74 HIGH-FREQUENCY POWER SOURCE (RF)
75 GROUND
76a, 76b, 76c, 76d, 76e MASS FLOW CONTROLLER (MFC)
79 HOLDER
78 GAS SUPPLY PART
80 GAS INTRODUCTION PART
81 COOLING WATER PIPE
82 COOLING WATER PATH
84 MAGNET
85 COOLING JACKET
86 INSULATING MATERIAL
87 TARGET
88 HOLDER
90, 90a, 90b, 90c PORT
98 MIRROR
98a Al LAYER
98b SiO₂ LAYER
98c Nb₂O_{X} LAYER
140 PUMP UNIT (EXHAUST DEVICE)
141 ATTACHMENT FLANGE
143 DRIVE DEVICE SUPPORT
150 FLOW REGULATING VALVE
151 FLOW PATH
152 OPENING
153 LIFTING VALVE
160 SERVO ACTUATOR
161 WORM JACK
162 LIFTING SHAFT
163 CONNECTOR
165 VALVE GUIDE
166 GUIDE ENGAGEMENT PORTION
170 TURBO MOLECULAR PUMP
171 PUMP FLANGE
D GAS SUPPLY LENGTH
E PLACEMENT LENGTH
F EXHAUST PORT LENGTH
G ELECTRODE LENGTH
H PROJECTION LENGTH
P0, P1, P2 PRESSURE
t0, t1, t2, t3 TIME
W, Wa, Wb, Wc WORKPIECE

1. A surface treatment apparatus comprising:
a housing unit that houses at least one workpiece;
a placement device that includes a rotating shaft extending in a horizontal direction, and on which the workpiece is placed such that a surface of the workpiece is substantially orthogonal to a normal direction of an outer peripheral surface of the rotating shaft, and faces outward;
a first rotating device that rotates the placement device in a predetermined rotation pattern around the rotating shaft in a state where the placement device is housed in the housing unit;
a surface treatment device that extends inside the housing unit and in parallel with the rotating shaft, and performs at least one type of surface treatment by supplying gas to the surface of the workpiece; and
an exhaust device that is provided inside the housing unit at a position different from a position where the surface treatment device is provided, adjusts pressure inside the housing unit, and exhausts the gas inside the housing unit.

2. The surface treatment apparatus according to claim 1, wherein
the exhaust device is provided horizontally in a lower part of the housing unit.

3. The surface treatment apparatus according to claim 1, wherein
the placement device includes a sealing member that seals the housing unit when the placement device is housed in the housing unit.

4. The surface treatment apparatus according to claim 1, wherein
the placement device includes a plurality of placement devices, and
the surface treatment apparatus further comprises a selection device that selects one placement device to be housed in the housing unit from the plurality of placement devices.

5. The surface treatment apparatus according to claim 4, wherein
the selection device includes a second rotating device that rotates any one of the plurality of placement devices to a position facing a housing port of the housing unit.

6. The surface treatment apparatus according to claim 1, further comprising a conveyance device that conveys the workpiece placed on the placement device in an axial direction of the rotating shaft so as to house the workpiece in the housing unit or carry the workpiece out of the housing unit.

7. The surface treatment apparatus according to claim 1, wherein
the surface treatment device is a plasma treatment apparatus that extends inside the housing unit and in parallel with the rotating shaft of the placement device, and performs surface treatment of the workpiece by supplying a reaction gas to an electrode to which high-frequency power is applied to convert the reaction gas to plasma, and spraying, to the workpiece, a precursor generated by causing the reaction gas converted to plasma to react with a film-forming gas.

8. The surface treatment apparatus according to claim 7, wherein the plasma treatment apparatus is provided on an upper inner wall surface of the housing unit.

9. The surface treatment apparatus according to claim 7, wherein
the plasma treatment apparatus includes a plurality of supply pipes for the film-forming gas, and
a supply amount of the film-forming gas is independently set for each of a plurality of workpieces placed in an extending direction of the rotating shaft, the workpiece including the plurality of workpieces.

10. The surface treatment apparatus according to claim 7, wherein
the plasma treatment apparatus includes a plurality of electrodes respectively corresponding to a plurality of workpieces placed in an extending direction of the rotating shaft, the workpiece including the plurality of workpieces, and
the high-frequency power to be supplied to each of the plurality of electrodes is independently set.

11. The surface treatment apparatus according to claim 7, wherein
a length of the electrode in a direction along a rotating direction of the placement device is 10% to 50% of a projection length obtained by projecting the placement device to a direction of the electrode.

12. The surface treatment apparatus according to claim 1, wherein
the surface treatment device is a sputtering apparatus that performs sputtering on the workpiece.

13. A surface treatment method comprising:
placing at least one workpiece such that a surface of the workpiece is substantially orthogonal to a normal direction of an outer peripheral surface of a rotating shaft extending in a horizontal direction, and faces outward;
performing at least one type of surface treatment by rotating the workpiece in a predetermined rotation pattern around the rotating shaft in a state where the workpiece is housed in a housing unit, and supplying gas to the surface of the workpiece from a surface treatment device that extends inside the housing unit in a direction parallel to the rotating shaft; and
adjusting pressure inside the housing unit and exhausting the gas inside the housing unit by an exhaust device provided inside the housing unit at a position different from a position where the surface treatment device is provided.
